(19) United States
(12) Patent Application Publication
(10) Pub. No.: US 2026/0182046 A1
(43) Pub. Date: Jun. 25, 2026

(54) ELECTROSTATIC DISCHARGE SEMICONDUCTOR DEVICE AND METHOD FOR MANUFACTURING THE SAME, INTEGRATED CIRCUIT

(71) Applicant: Joulwatt Technology Co., Ltd., Hangzhou (CN)

(72) Inventor: Tao HU, Hangzhou (CN)

(21) Appl. No.: 19/124,821

(22) PCT Filed: Jan. 17, 2024
(86) PCT No.: PCT/CN2024/072700

§ 371 Date: Apr. 25, 2025

(30) Foreign Application Priority Data
Feb. 28, 2023 (CN) 202310207316.7

(51) Int. Cl. H10D 89/60; H10D 30/60; H10D 62/10; H10D 62/13; H10D 62/17; H10W 42/60

(52) U.S. Cl. CPC H10D 89/711; H10D 30/603; H10D 62/107; H10D 62/108; H10D 62/157; H10D 62/393; H10D 89/601; H10D 89/713; H10W 42/60

(57) ABSTRACT

An electrostatic discharge semiconductor device and a method for manufacturing the same, an integrated circuit are disclosed. The electrostatic discharge semiconductor device includes: a substrate; a first N-type well region and a drift region; a P-type well region and a second N-type well region in contact with each other; a first N+ doped region and a first P+ doped region; a second P+ doped region and a second N+ doped region; a plurality of field oxide layers, separating the first N+ doped region, the first P+ doped region, the second P+ doped region, and the second N+ doped region in sequence; a gate oxide layer and a polysilicon layer, stacked in sequence on the surface of the substrate. Under electrostatic pulses, the parasitic transistor turns on first, then a controllable silicon discharge path is formed, the device has strong electrostatic protection capability and high robustness.

This application is a Section 371 National Stage application of International application NO. PCT/CN2024/072700, and claims the priority of a Chinese patent application filed on Feb. 28, 2023, with the application No. 2023102073167, titled “ELECTROSTATIC DISCHARGE SEMICONDUCTOR DEVICE AND METHOD FOR MANUFACTURING THE SAME, INTEGRATED CIRCUIT,” the contents of which are incorporated herein by reference, including the entire specification, claims, drawings, and abstract.

### FIELD OF TECHNOLOGY

The present disclosure relates to the field of semiconductor technology, and more specifically, to an electrostatic discharge semiconductor device, a method for manufacturing the same, and an integrated circuit.

### BACKGROUND

Electrostatic discharge (ESD) is a natural phenomenon that exists objectively throughout the entire lifecycle of a product. ESD, which is not easily perceived by humans, poses a serious threat to integrated circuit products. According to data from National Semiconductor, 38% of integrated circuit failures are caused by ESD/EOS (Electrical-Over-Stress). During the manufacturing, packaging, testing, and application stages of a chip, both the external environment and internal structure accumulate a certain amount of charge, which is always at risk of electrostatic threats. Therefore, it is necessary to place ESD protection devices on each pin during chip design. For high-voltage CMOS or high-voltage BCD processes, they are widely used in the manufacture of integrated circuit products for power management, high-voltage driving, and automotive electronics. The high-voltage pins of these products often use LDMOS (laterally-diffused metal-oxide semiconductor) or SCR (Silicon Controlled Rectifier) structures as ESD protection devices. However, these integrated circuit products often operate in environments with large currents, high voltages, and strong electromagnetic interference, where ESD protection devices may exhibit low robustness and false triggering issues.

FIG. 1 is a sectional view of the LDMOS semiconductor structure of the prior art. As shown in FIG. 1, taking PLDMOS as an example, it includes a P-type substrate 101, an N-type well region 103 and a P-type doped drift region 102 located on the upper part of the substrate 101, and a P-type well region 104 located on the upper part of the drift region 102. A first P+ doped region 131 and a first N+ doped region 132 are formed in the N-type well region 103, and a second P+ doped region 133 is formed in the P-type well region 104. Field oxide layers 111 and 112 are formed on the surface of the substrate 101, and a gate oxide layer 121 and a polysilicon layer 122 are formed above the field oxide layer 112. To achieve high hold voltage ESD characteristics, the source, body, and gate of the PLDMOS are short-circuited as the anode, and the drain end is the cathode. When an ESD pulse arrives, the N-type well region 103 and the drift region 102 undergo avalanche breakdown, parasitic PNP current discharge, but due to the low robustness of PNP as an ESD protection device, a larger device area is needed to achieve a higher HBM (Human Body Model) level, and the current ESD protection capability of LDMOS devices is poor.

### SUMMARY OF THE DISCLOSURE

In view of the above problems, the purpose of the present disclosure is to provide an electrostatic discharge semiconductor device, a method for manufacturing the same, and an integrated circuit to solve the problems in the existing technology.

According to the first aspect of the present disclosure, an electrostatic discharge semiconductor device is provided, which includes:
a substrate;
a first N-type well region and a drift region disposed laterally at the upper part of the substrate;
a P-type well region and a second N-type well region in contact with each other and disposed at the upper part of the drift region, away from the first N-type well region;
a first N+ doped region and a first P+ doped region, located on one side of the first N-type well region away from the drift region;
a second P+ doped region and a second N+ doped region, respectively located in the P-type well region and the second N-type well region;
a plurality of field oxide layers, located on the surface of the substrate, separating the first N+ doped region, the first P+ doped region, the second P+ doped region, and the second N+ doped region in sequence;
a gate oxide layer and a polysilicon layer, stacked in sequence on the surface of the substrate between the first N-type well region and the drift region,
wherein, the second P+ doped region extends across the P-type well region and the second N-type well region.

Optionally, the P-type well region and the second N-type well region are disposed laterally adjacent within the drift region.

Optionally, the second N-type well region is located at the upper part of the P-type well region, away from the first N-type well region.

Optionally, the first N+ doped region, the first P+ doped region, and the polysilicon layer are all connected to the anode of the semiconductor device, and the second P+ doped region and the second N+ doped region are both connected to the cathode of the semiconductor device.

Optionally, when the semiconductor device is operating, a transistor structure composed of the first P+ doped region, the first N-type well region, and the drift region is turned on to form a first current discharge path from the anode to the cathode.

Optionally, when the semiconductor device is operating, a controllable silicon structure composed of the first P+ doped region, the first N-type well region, the drift region, the P-type well region, and the second N-type well region is turned on to form a second current discharge path from the anode to the cathode.

Optionally, when the semiconductor device receives an electrostatic pulse, the first current discharge path is activated before the second current discharge path.

Optionally, the electrostatic discharge semiconductor device further includes: a silicide blocking layer located on the side of the second P+ doped region away from the second N+ doped region.

According to the second aspect of the present disclosure, a method of manufacturing an electrostatic discharge semiconductor device is provided, which includes:
forming a substrate and a drift region disposed at the upper part of the substrate;
forming a plurality of field oxide layers on the surface of the substrate;
forming a first N-type well region, a P-type well region, and a second N-type well region being separated from each other in sequence at the upper part of the substrate, with the P-type well region and the second N-type well region disposed within the drift region;
forming stacked gate oxide layer and polysilicon layer on the surface of the substrate between the first N-type well region and the drift region;
forming a first N+ doped region and a first P+ doped region in the first N-type well region; and
forming a second P+ doped region and a second N+ doped region in the P-type well region and the second N-type well region, respectively,
wherein, the second P+ doped region extends across the P-type well region and the second N-type well region.

Optionally, the method of manufacturing the electrostatic discharge semiconductor device further includes:
forming a polysilicon blocking layer on the side of the second P+ doped region away from the second N+ doped region; and
forming an anode and a cathode of the semiconductor device, wherein the anode is coupled to the first N+ doped region, the first P+ doped region, and the polysilicon layer; the cathode is coupled to the second N+ doped region and the second P+ doped region.

According to the third aspect of the present disclosure, an integrated circuit is provided, which includes: the electrostatic discharge semiconductor device described above.

The electrostatic discharge semiconductor device, the method for manufacturing the same, and the integrated circuit provided by the present disclosure, based on the PLDMOS semiconductor structure, have been improved by adding an N-type well region in contact with the P-type well region at the drain end and an N-type doped region (N+ doped region) located in the N-type well region, and making the P+ doped region in the P-type well region at the drain end span the N-type well region, resulting in a controllable silicon structure semiconductor device. The series of structural improvements at the drain end enable the parasitic PNP transistor near the source end to form a current discharge path first when an electrostatic pulse arrives, and then, as the current increases, the parasitic NPN transistor near the drain end also turns on to form a controllable silicon current discharge path, thereby providing extremely high electrostatic protection capability, high robustness, and improving the current discharge efficiency per unit area of the semiconductor device. The process is relatively simple and easy to operate; moreover, the parasitic PNP turning on first can prevent the latch-up effect caused by false triggering of the SCR device due to voltage overshoot or spike peaks at the pin.

Optionally, to accelerate the current discharge of the SCR structure, a silicide blocking layer SAB (Salicide block) is also formed above the P+ doped region at the drain end to increase the parasitic resistance of the parasitic transistor, so that a smaller current can trigger the SCR to turn on more quickly, enhancing the electrostatic protection capability.

### BRIEF DESCRIPTION OF THE DRAWINGS

The above and other objects, features, and advantages of the present disclosure will be more clearly understood through the following description of the embodiments with reference to the accompanying drawings, in which:

FIG. 1 is a sectional view of the LDMOS semiconductor structure of the prior art;

FIG. 2 is a sectional view of a controllable silicon device for electrostatic protection;

FIG. 3 is a sectional view of the electrostatic discharge semiconductor device according to an embodiment of the present disclosure;

FIGS. 4A to 4E are sectional views of each stage of the manufacturing method of the electrostatic discharge semiconductor device according to an embodiment of the present disclosure.

### DETAILED DESCRIPTION OF THE DISCLOSURE

The following will describe the various embodiments of the present disclosure in more detail with reference to the drawings. In the various drawings, the same components are represented by the same or similar reference numerals. For clarity, the various parts in the drawings are not drawn to scale. In addition, some well-known parts may not be shown. For simplicity, a semiconductor structure obtained after several steps can be described in one figure.

When describing the structure of the device, when a layer or a region is referred to as being “above” or “on top of” another layer or region, it can mean directly above the other layer or region, or there may be other layers or regions between them. Moreover, if the device is flipped, the layer or region will be “below” or “underneath” the other layer or region.

If describing the situation where one layer or region is directly above another, this document will use expressions such as “A is directly on top of B” or “A is on top of B and adjacent to it.” In this application, “A is directly located in B” means that A is located in B and A is directly adjacent to B, not that A is located in the doping region formed in B.

Unless specifically indicated in the following text, the various layers or regions of the semiconductor device can be made of materials known to those skilled in the art. Semiconductor materials include, for example, III-V semiconductors such as GaAs, InP, GaN, SiC, and IV semiconductors such as Si, Ge. Gate conductors, electrode layers can be formed from various conductive materials, such as metal layers, doped polysilicon layers, or stacked gate conductors including metal layers and doped polysilicon layers or other conductive materials, such as TaC, TiN, TaSiN, HfSiN, TiSiN, TiCN, TaAlC, TiAlN, TaN, PtSix, Ni3Si, Pt, Ru, W, and combinations of the aforementioned conductive materials.

In this application, the term “semiconductor structure” refers to the collective name for the entire semiconductor structure formed in each step of manufacturing a semiconductor device, including all layers or regions that have been formed. The term “laterally extending” refers to extending in a direction roughly perpendicular to the trench depth direction.

Below, combined with the drawings and examples, a further detailed description of the specific implementation of the present disclosure is provided.

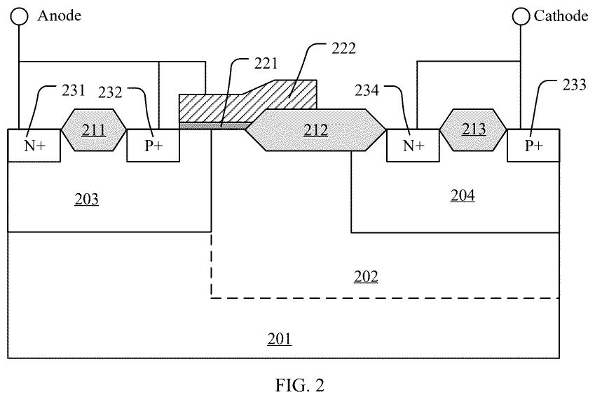

FIG. 2 is a sectional view of a controllable silicon device for electrostatic protection.

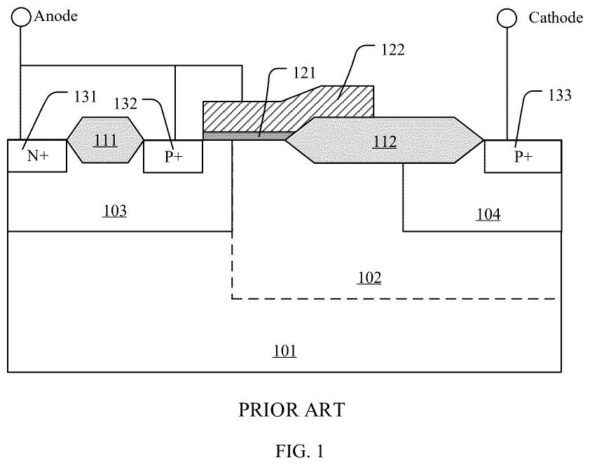

As described above for FIG. 1, the robustness of the PLDMOS device is poor, and the current capacity per unit area is relatively poor, so the structure of the LDMOS device is improved by inserting an N+ doped region at the drain end to form the SCR structure as shown in FIG. 2. The PLDMOS-SCR serves as an ESD protection device and has excellent robustness and unit area efficiency, capable of passing higher HBM tests.

As shown in FIG. 2, the controllable silicon device includes a substrate 201, an N-type well region 203 and a P-type lightly doped drift region 202 distributed laterally on the upper part of the substrate 201, and a P-type well region 204 located on the upper part of the doped region 202, away from the N-type well region 203. A first N+ doped region 231 and a first P+ doped region 232 are formed in the N-type well region 203, and a second N+ doped region 234 and a second P+ doped region 233 are formed in the P-type well region 204. Field oxide layers 211, 212, and 213 are formed on the surface of the substrate 201 to separate multiple P+ or N+ doped regions, with the sides of the field oxide layers being bird's beak structures, and a gate oxide layer 221 and a polysilicon layer 222 are formed on the side of field oxide layer 212 near the N-type well region 203, stacked on the surface of the substrate 201. Compared to the LDMOS structure in FIG. 1, the SCR structure only adds a second N+ doped region 234 inside the P-type well region 204 at the drain end, separated by field oxide layer 213 from the two doped regions, while the first P+ doped region 232 at the source end, the first N+ doped region 231 in the body region, and the polysilicon layer 222 at the gate end are connected to form the anode of the SCR structure, and the second P+ doped region 233 and the second N+ doped region 234 are connected to the cathode, but the current discharge path between the anode and the cathode is changed. The SCR structure can be regarded as being composed of parasitic PNP and NPN transistors between the anode and the cathode, with the first P+ doped region 232, the N-type well region 203, the drift region 202, and the P-type well region 204 being regarded as the PNP transistor, and the N-type well region 203, the P-type well region 204, and the second N+ doped region 234 being regarded as the NPN transistor. The SCR structure has a very low holding voltage (Vth) after being triggered by static electricity. If the chip experiences a certain degree of voltage overshoot or voltage spike during testing or operation, causing the SCR device to be falsely triggered and maintained at a very low voltage value, it will cause a latch-up effect and burn out the chip.

Specifically, as shown in FIG. 2, the PLDMOS-SCR structure is mainly composed of two parasitic transistors. When a positive ESD pulse arrives, the positive voltage causes the PN junction formed by the N-type well region 203 and the drift region 202 in the SCR to be reverse-biased. As the ESD voltage gradually increases, the PN junction gradually enters an avalanche breakdown state. The holes generated by the avalanche breakdown of the PN junction flow from the N-type well region 203 into the P-type well region 204 and are finally collected by the second P+ doped region 233 in the P-type well region 204, generating a current IPW; similarly, the electrons generated flow from the drift region 202 into the N-type well region 203 and are finally collected by the first N+ doped region 231 in the N-type well region 203, generating a current INW. Since there are parasitic resistances RN-Well and RP-Well in the N-type well region 203 and the P-type well region 204, voltage drops will form on the N-type well region 203 and the P-type well region 204. When the voltage drop on the N-type well region 203 or the P-type well region 204 reaches 0.7 V, one of the parasitic transistors NPN or PNP will turn on. When one transistor turns on, the voltage drop caused by the current generated on its collector will immediately turn on the other parasitic transistor. Eventually, the two transistors form an open-loop positive feedback mechanism, and the SCR fully turns on, forming a low-resistance path, with the voltage clamped at a very low value, causing a latch-up effect and burning out the chip. Therefore, the SCR structure has poor electrostatic protection effect on overvoltage or spike peaks at the pin.

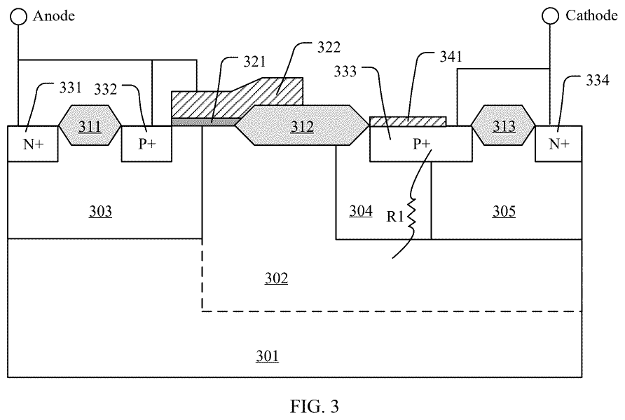

Therefore, the LDMOS structure of FIG. 1 is further improved by adding an N-type well region and an N+ doped region at the drain end of the traditional PLDMOS, and the P+ doped region at the drain end spans both the P-type well region and the N-type well region, forming the semiconductor device as shown in FIG. 3. Then, under the ESD pulse, the parasitic PNP turns on first, and when the current continues to increase, the voltage drop on the parasitic resistance R1 in the P-type well region 304 at the drain end reaches the PN junction conduction voltage drop, and the parasitic diode composed of the P-type well region 304 and the second N-type well region 305 turns on, followed by the SCR turning on, preventing the latch-up effect caused by overvoltage at the pin. The following is a specific introduction combined with FIG. 3.

FIG. 3 is a sectional view of the electrostatic discharge semiconductor device according to an embodiment of the present disclosure.

As shown in FIG. 3, the semiconductor device includes a substrate 301, a first N-type well region 303 and a drift region 302 distributed laterally on the upper part of the substrate 301, and a P-type well region 304 and a second N-type well region 305 in contact with each other, distributed at the upper part of the drift region 302, away from the first N-type well region 303. The substrate 301 and the drift region 302 are both P-type doped regions. The semiconductor device also includes sequentially separated first N+ doped region 331, first P+ doped region 332, second P+ doped region 333, and second N+ doped region 334. The first N+ doped region 331 and the first P+ doped region 332 are located on one side of the first N-type well region 303 away from the drift region 302, and the first N+ doped region 331 is further away from the drift region 302 than the first P+ doped region 332. The second P+ doped region 333 and the second N+ doped region 334 are respectively located in the P-type well region 304 and the second N-type well region 305.

The surface of the substrate 301 also includes multiple field oxide layers, with field oxide layers 311, 312, and 313 sequentially separating the first N+ doped region 331, the first P+ doped region 332, the second P+ doped region 333, and the second N+ doped region 334, and the growth of each field oxide layer is a conventional process. The sides of each field oxide layer are bird's beak structures, and a gate oxide layer 321 is formed on the side of field oxide layer 312 near the first P+ doped region 332. The gate oxide layer 321 and the polysilicon layer 322 are stacked on the surface of the substrate 301 between the first N-type well region 303 and the drift region 302, with the polysilicon layer 322 also covering part of the surface of field oxide layer 312.

Furthermore, the P-type well region 304 and the second N-type well region 305 being in contact means that the P-type well region 304 and the second N-type well region 305 are laterally adjacent and distributed on the upper part of the drift region 302, away from the first N-type well region 303. Alternatively, the P-type well region 304 and the second N-type well region 305 being in contact means that the second N-type well region 305 is located at the upper part of the P-type well region 304, away from the first N-type well region 303. The second P+ doped region 341 spans both the P-type well region 304 and the second N-type well region 305.

Furthermore, the first N+ doped region 331 is the body region, the first P+ doped region 332 is the source region, and the polysilicon layer 322 is the gate. The first N+ doped region 331, the first P+ doped region 332, and the polysilicon layer 322 are all connected to the anode of the semiconductor device, and the second P+ doped region 333 and the second N+ doped region 334 are both connected to the cathode of the semiconductor device, thereby forming two current discharge paths from the anode to the cathode when the semiconductor device is operating.

As shown in FIG. 3, when the semiconductor device is operating in the forward direction, i.e., when the voltage on the anode is greater than the voltage on the cathode, the parasitic PNP transistor structure composed of the first P+ doped region 332, the first N-type well region 303, and the drift region 302 turns on to form the first current discharge path (anode—first P+ doped region 332—first N-type well region 303—drift region 302—P-type well region 304—second P+ doped region 333—cathode). Additionally, the controllable silicon structure composed of the first P+ doped region 332, the first N-type well region 303, the drift region 302, the P-type well region 304, and the second N-type well region 305 turns on to form the second current discharge path (anode—first P+ doped region 332—first N-type well region 303—drift region 302—P-type well region 304—second N-type well region 305—second N+ doped region 334—cathode, equivalent to passing through a P-N-P-N structure).

Specifically, the first P+ doped region 332, the first N-type well region 303, and the drift region 302 can be regarded as a parasitic PNP transistor structure, and the first N-type well region 303, the P-type well region 304, and the second N-type well region 305 can be regarded as a parasitic NPN transistor structure. When an ESD pulse arrives, the PN junction formed by the first N-type well region 303 and the drift region 302 is reverse-biased and undergoes avalanche breakdown. The electrons generated flow from the drift region 302 into the first N-type well region 303 and are collected by the first N+ doped region 331 in the first N-type well region 303, generating a current INW. The voltage drop on the resistance in the first N-type well region 303 causes holes to flow from the first N-type well region 303 through the drift region 302 into the P-type well region 304. Since the second P+ doped region 333 spans two different types of well regions, the presence of the second N-type well region 305 limits the collection of holes by the second P+ doped region 333, resulting in a smaller current IPW. The rate of voltage drop increase on the resistance in the P-type well region 304 is slower than that on the resistance in the first N-type well region 303. Thus, when the voltage drop on the first N-type well region 303 reaches 0.7 V, the parasitic transistor PNP turns on first to discharge the current, forming the first current discharge path.

When the current continues to increase, the voltage drop on the parasitic resistance R1 in the P-type well region 304 at the drain end reaches the PN junction conduction voltage drop, and the parasitic diode composed of the P-type well region 304 and the second N-type well region 305 turns on, and the parasitic NPN transistor from the anode to the cathode also turns on, forming the SCR discharge path, i.e., the second current discharge path. At this time, the SCR and PNP jointly discharge the ESD current. Therefore, this embodiment inserts an N-type well region 305 and a second N+ doped region 334 at the drain end of the traditional PLDMOS device, and the second P+ doped region 333 spans both the P-type well region 304 and the second N-type well region 305, enabling the semiconductor device to activate the first current discharge path before the second current discharge path when receiving an electrostatic pulse, avoiding the latch-up effect caused by overvoltage or spike peaks at the pin. Moreover, when the electrostatic current is large, the two current discharge paths discharge the current simultaneously, enhancing the current discharge capability per unit area. Therefore, this semiconductor device combines the characteristic of no hysteresis of PNP and the high robustness of SCR, increasing the current efficiency per unit area of the ESD device while preventing the latch-up caused by overvoltage at the pin.

In a further embodiment, to enable the SCR current discharge path to turn on more quickly, a SAB layer (Salicide block, silicide blocking layer) is also formed on the surface of the second P+ doped region 333 on the left side to increase the parasitic resistance on the PNP path, i.e., the electrostatic discharge semiconductor device further includes a silicide blocking layer located on the side of the second P+ doped region 333 away from the second N+ doped region 334, allowing a smaller current to trigger the SCR to turn on, thereby enhancing the current discharge capability.

In summary, this embodiment of the electrostatic discharge semiconductor device, based on the PLDMOS semiconductor structure, has been improved by adding an N-type well region in contact with the P-type well region at the drain end and an N-type doped region (N+ doped region) located in the N-type well region, and making the P+ doped region in the P-type well region at the drain end span the N-type well region, resulting in a controllable silicon structure semiconductor device. The series of structural improvements at the drain end enable the parasitic PNP transistor near the source end to form a current discharge path first when an electrostatic pulse arrives, and then, as the current increases, the parasitic NPN transistor near the drain end also turns on to form a controllable silicon current discharge path, thereby providing extremely high electrostatic protection capability, high robustness, and improving the current discharge efficiency per unit area of the semiconductor device. The process is relatively simple and easy to operate; moreover, the parasitic PNP turning on first can prevent the latch-up effect caused by false triggering of the SCR device due to voltage overshoot or spike peaks at the pin.

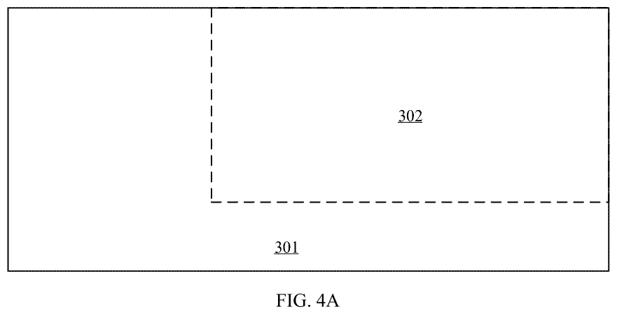

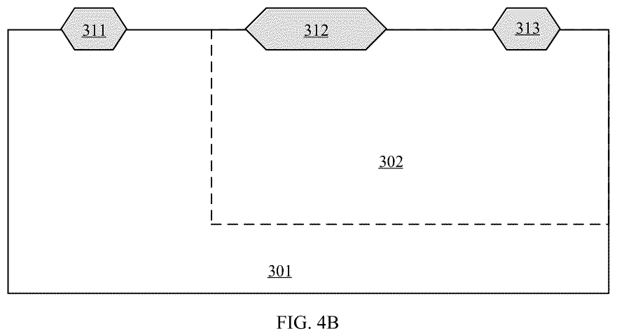

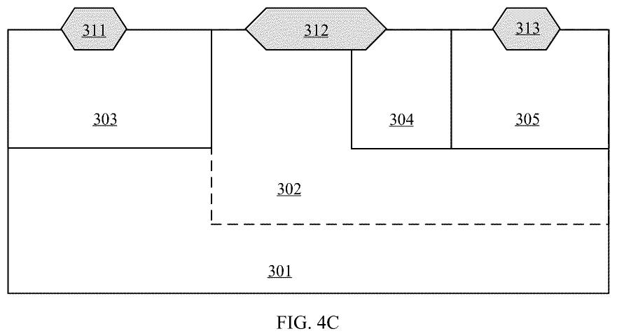

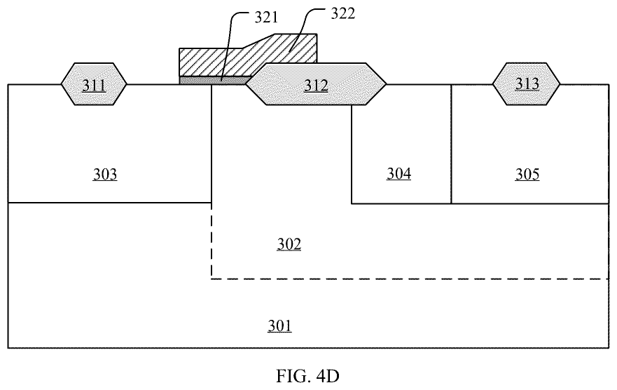

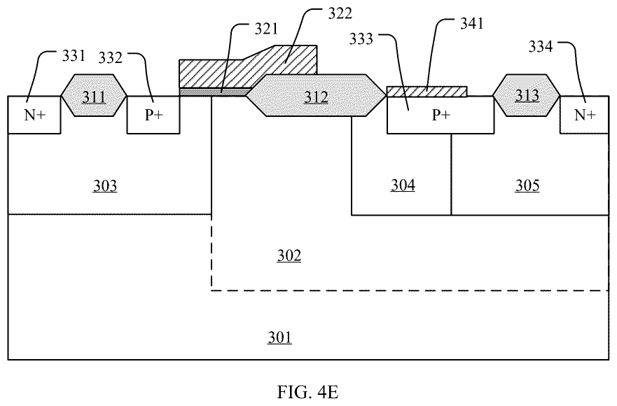

FIGS. 4A to 4E show the sectional views of each stage of the manufacturing method of the electrostatic discharge semiconductor device according to an embodiment of the present disclosure. The semiconductor device structure shown in FIG. 3 is made through the process steps of FIGS. 4A to 4E to further enhance the electrostatic protection capability of the semiconductor device, and the following describes the manufacturing process of the semiconductor device of this embodiment with reference to FIGS. 4A to 4E.

As shown in FIG. 4A, the substrate 301 and the drift region 302 located on the upper part of the substrate 301 are first formed. A small amount of ions are injected into the semiconductor substrate 301, and the well is pushed at high temperature to form a lightly doped P-type region, i.e., the drift region 302. This step is completed using conventional processes. The substrate 301, for example, is a silicon substrate.

Furthermore, as shown in FIG. 4B, multiple field oxide layers are formed on the surface of the substrate 301. Field oxide isolation is performed on the surface of the substrate 301, i.e., multiple isolated field oxide layers are formed, i.e., field oxide layers 311 to 313 are formed. The formation of the field oxide layers is a conventional process, for example, an oxide layer is deposited on the surface of the substrate 301, then a hard mask is deposited, followed by etching using the mask, and finally, field oxidation growth is performed at high temperature, and the hard mask is removed. The specific process is not detailed. After the field oxide production step is completed, the structure shown in FIG. 4B is formed, in which the length of field oxide layer 312 is longer.

Next, as shown in FIG. 4C, the first N-type well region 303, the P-type well region 304, and the second N-type well region 305, which are sequentially separated, are formed on the upper part of the substrate 301, with the P-type well region 304 and the second N-type well region 305 located within the drift region 302. Well region injection is performed along the surface of the substrate 301, forming the first N-type well region 303 on the left upper part of the substrate 301, and forming the P-type well region 304 and the second N-type well region 305 in the drift region 302.

Next, as shown in FIG. 4D, the stacked gate oxide layer 321 and polysilicon layer 322 are formed on the surface of the substrate 301 between the first N-type well region 303 and the drift region 302. The polysilicon layer 322 is made above the field oxide layer 312, covering part of the field oxide layer 312 and part of the first N-type well region 303, and a gate oxide layer 321 is also formed on the side of field oxide layer 312 near the first N-type well region 303, and below the polysilicon layer 322. The formation process of the gate oxide layer 321 and the polysilicon layer 322 is a conventional process, for example, the polysilicon layer 322 is formed by chemical vapor deposition, and the details are not specified here.

Furthermore, as shown in FIG. 4E, the first N+ doped region 331 and the first P+ doped region 332 are formed in the first N-type well region 303, and the second P+ doped region 333 and the second N+ doped region 334 are formed in the P-type well region 304 and the second N-type well region 305, respectively. P+ or N+ injection is performed in the first N-type well region 303, the P-type well region 304, and the second N-type well region 305 to form multiple P+ doped regions or N+ doped regions, and the second P+ doped region 333 spans the P-type well region 304 and the second N-type well region 305.

Furthermore, a polysilicon blocking layer 341 is formed on the side of the second P+ doped region 333 away from the second N+ doped region 334.

Furthermore, the anode and cathode of the semiconductor device are formed, with the anode connected to the first N+ doped region 331, the first P+ doped region 332, and the polysilicon layer 322, and the cathode connected to the second N+ doped region 333 and the second P+ doped region 334 to form the structure of FIG. 3. The manufacturing of the electrode layer above the first N+ doped region 331, the first P+ doped region 332, the polysilicon layer 322, the second N+ doped region 333, and the second P+ doped region 334 is omitted here.

This semiconductor device achieves the HBM electrostatic protection capability of the device and retains the high robustness of the SCR structure. At the same time, the preparation process is compatible with the original LDMOS and other structure preparation processes, which is easy to implement.

In addition, the present disclosure also provides an integrated circuit, which includes the electrostatic discharge semiconductor device described in the above embodiment.

In summary, the electrostatic discharge semiconductor device, the method for manufacturing the same, and the integrated circuit provided by this embodiment, based on the PLDMOS semiconductor structure, have been improved by adding an N-type well region in contact with the P-type well region at the drain end and an N-type doped region (N+ doped region) located in the N-type well region, and making the P+ doped region in the P-type well region at the drain end span the N-type well region, resulting in a controllable silicon structure semiconductor device. The series of structural improvements at the drain end enable the parasitic PNP transistor near the source end to form a current discharge path first when an electrostatic pulse arrives, and then, as the current increases, the parasitic NPN transistor near the drain end also turns on to form a controllable silicon current discharge path, thereby providing extremely high electrostatic protection capability, high robustness, and improving the current discharge efficiency per unit area of the semiconductor device. The process is relatively simple and easy to operate; moreover, the parasitic PNP turning on first can prevent the latch-up effect caused by false triggering of the SCR device due to voltage overshoot or spike peaks at the pin.

Optionally, to accelerate the current discharge of the SCR structure, a silicide blocking layer SAB (Salicide block) is also formed above the P+ doped region at the drain end to increase the parasitic resistance of the parasitic transistor, so that a smaller current can trigger the SCR to turn on more quickly, enhancing the electrostatic protection capability.

As described above, these embodiments of the present disclosure do not exhaustively describe all the details, nor do they limit the disclosure to the specific embodiments described. Obviously, many modifications and variations can be made based on the above description. The specification selects and specifically describes these embodiments to better explain the principles and practical applications of the disclosure, enabling those skilled in the art to make good use of the disclosure and modifications based on the disclosure. The disclosure is only limited by the claims and their entire scope and equivalents.

1. An electrostatic discharge semiconductor device, comprising:
a substrate;
a first N-type well region and a drift region disposed laterally at an upper portion of the substrate;
a P-type well region and a second N-type well region in contact with each other and disposed at an upper portion of the drift region, away from the first N-type well region;
a first N+ doped region and a first P+ doped region, disposed on one side of the first N-type well region away from the drift region;
a second P+ doped region and a second N+ doped region, respectively disposed in the P-type well region and the second N-type well region;
a plurality of field oxide layers, disposed on a surface of the substrate, separating the first N+ doped region, the first P+ doped region, the second P+ doped region, and the second N+ doped region in sequence;
a gate oxide layer and a polysilicon layer, stacked on the surface of the substrate in sequence, between the first N-type well region and the drift region,
wherein, the second P+ doped region extends across the P-type well region and the second N-type well region.

2. The electrostatic discharge semiconductor device according to claim 1, wherein the P-type well region and the second N-type well region are disposed within the drift region, adjacent to each laterally.

3. The electrostatic discharge semiconductor device according to claim 1, wherein the second N-type well region is disposed at an upper portion of the P-type well region, away from the first N-type well region.

4. The electrostatic discharge semiconductor device according to claim 1, wherein the first N+ doped region, the first P+ doped region, and the polysilicon layer are all coupled to an anode of the semiconductor device, and the second P+ doped region and the second N+ doped region are both coupled to a cathode of the semiconductor device.

5. The electrostatic discharge semiconductor device according to claim 4, wherein, when the semiconductor device is operating, a transistor structure composed of the first P+ doped region, the first N-type well region, and the drift region is turned on to form a first current discharge path from the anode to the cathode.

6. The electrostatic discharge semiconductor device according to claim 5, wherein, when the semiconductor device is operating, a controllable silicon structure composed of the first P+ doped region, the first N-type well region, the drift region, the P-type well region, and the second N-type well region is turned on to form a second current discharge path from the anode to the cathode.

7. The electrostatic discharge semiconductor device according to claim 6, wherein, when the semiconductor device receives an electrostatic pulse, the first current discharge path is activated before the second current discharge path.

8. The electrostatic discharge semiconductor device according to claim 1, further comprising: a silicide blocking layer disposed on the side of the second P+ doped region away from the second N+ doped region.

9. A method for manufacturing an electrostatic discharge semiconductor device, comprising:
forming a substrate and a drift region disposed at an upper portion of the substrate;
forming a plurality of field oxide layers on a surface of the substrate;
forming a first N-type well region, a P-type well region, and a second N-type well region being separated from each other in sequence at an upper portion of the substrate, with the P-type well region and the second N-type well region disposed within the drift region;
forming stacked gate oxide layer and polysilicon layer on the surface of the substrate between the first N-type well region and the drift region;
forming a first N+ doped region and a first P+ doped region in the first N-type well region; and
forming a second P+ doped region and a second N+ doped region in the P-type well region and the second N-type well region, respectively,
wherein, the second P+ doped region extends across the P-type well region and the second N-type well region.

10. The method for manufacturing an electrostatic discharge semiconductor device according to claim 9, further comprising:
forming a polysilicon blocking layer on a side of the second P+ doped region away from the second N+ doped region; and
forming an anode and a cathode of the semiconductor device, wherein the anode is coupled to the first N+ doped region, the first P+ doped region, and the polysilicon layer; the cathode is coupled to the second N+ doped region and the second P+ doped region.

11. An integrated circuit, comprising: an electrostatic discharge semiconductor device of claim 1.
